(19) United States
(12) Patent Application Publication
(10) Pub. No.: US 2013/0258608 A1
(43) Pub. Date: Oct. 3, 2013

(54) MOUNTING APPARATUS FOR POWER SUPPLY UNIT

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/525,380

(22) Filed: Jun. 18, 2012

(30) Foreign Application Priority Data
Mar. 29, 2012 (CN) 201210087169.6

(51) Int. Cl. H05K 7/00

(52) U.S. Cl. 361/747

(57) ABSTRACT

A mounting apparatus includes a bottom plate, a frame mounted on the bottom plate for receiving a power supply unit, and a lock member mounted on the frame. The frame includes two opposite side plates and an end plate connected between front ends of the side plates. A resilient tab is formed on each side plate. A protrusion is formed on an outer surface of each resilient tab. The lock member includes two opposite sidewalls, a top wall connected between tops of the sidewalls, and a stop plate extending down from a rear end of the top wall. The sidewalls respectively contact outer surfaces of the side plates. Each of the sidewalls defines an opening to allow a corresponding one of the protrusions to engage in.

### BACKGROUND

1. Technical Field

The present disclosure relates to an apparatus for mounting a power supply unit.

2. Description of Related Art

Power supply units are generally mounted in chassis by screws. However, these screws are small and difficult to handle, making the installation of the power supply unit in the chassis labor-intensive.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting apparatus together with a power supply unit.

FIG. 2 is an assembled, isometric view of the mounting apparatus and the power supply unit of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

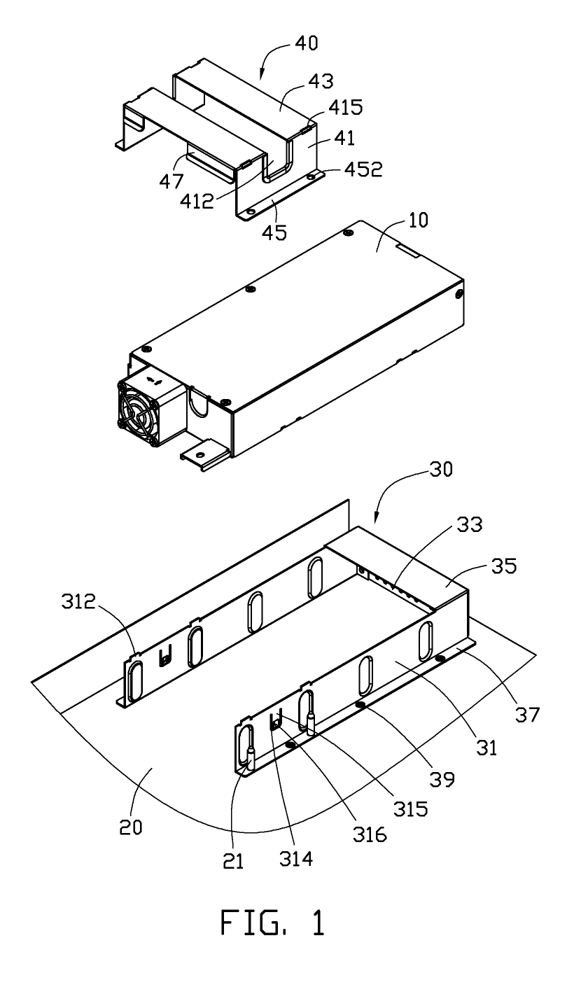

FIG. 1 shows an exemplary embodiment of a mounting apparatus for a power supply unit 10. The mounting apparatus includes a bottom plate 20, a frame 30 mounted on the bottom plate 20, and a lock member 40.

Two pairs of poles 21 are formed on the bottom plate 20 in a substantially perpendicular manner.

The frame 30 includes two opposite side plates 31, an end plate 33 connected between the front ends of the side plates 31, a top plate 35 connected between front portions of the tops of the side plates 31, and two fixing plates 37 respectively extending outwards from the bottoms of the side plates 31 in a substantially perpendicular manner A plurality of screws 39 are extended through the fixing plates 37 and engage in the bottom plate 20, to fix the frame 30 to the bottom plate 20. The pairs of poles 21 respectively extend through rear portions of the fixing plates 37. Two positioning tabs 312 extend upward from a rear portion of the top of each side plate 31. A resilient tab 315 is bound by an open top, and a substantially U-shaped slot 314 is formed on each side plate 31, below the corresponding positioning tabs 312. A protrusion 316 is formed on an outer surface of each resilient tab 315. A slanted surface (not labeled) is formed on a top of each protrusion 316.

The lock member 40 includes two opposite sidewalls 41, a top wall 43 connected between the tops of the sidewalls 41, two flanges 45 respectively extending outwards from the bottoms of the sidewalls 41 in a substantially perpendicular manner, and two substantially L-shaped stop plates 47 extending downwards and rearwards from the rear side of the top wall 43. An opening 412 is defined in a middle of each sidewall 41. Two through slots 415 are defined in a joint of the top wall 43 and each sidewall 41. Two through holes 452 are defined in each flange 45, corresponding to a corresponding pair of poles 21.

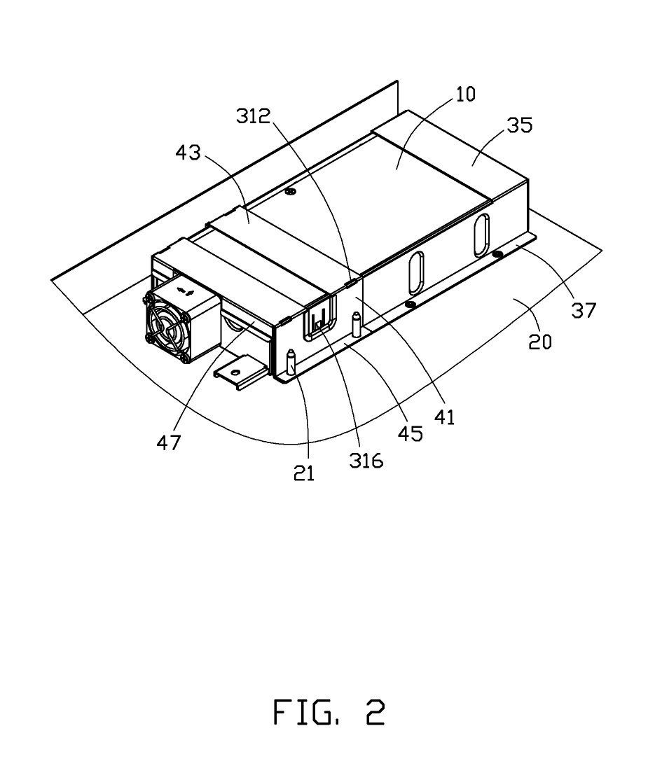

Referring to FIG. 2, in assembly, the power supply unit 10 is placed on the bottom plate 20, behind the frame 30. The power supply unit 10 is slid into the frame 30 between the side plates 31, until the front end of the power supply unit 10 abuts against the end plate 33. The lock member 40 is placed above the rear end of the frame 30, to allow the poles 21 to respectively align with the through holes 452. The lock member 40 is moved down. The poles 21 respectively extend through the through holes 452. The slanted surfaces of the protrusions 316 abut against the inner surfaces of the sidewalls 41, to inwardly deform the resilient tabs 315. The lock member 40 is moved further down. The positioning tabs 312 engage in the respective through slots 415. When the flanges 45 engage with the respective fixing plates 37, the protrusions 316 respectively align with the respective openings 412. The resilient tabs 315 are restored, to allow the bottoms of the protrusions 316 to engage with respective portions of the sidewalls 41 bounding the bottom ends of the openings 412. Thereby, the lock member 40 is mounted on the frame 30. The stop plates 47 engage with the rear end of the power supply unit 10, and the top plate 35 and the top wall 43 respectively engage with front and rear portions of the top of the power supply unit 10. Thereby, the power supply unit 10 is sandwiched between the frame 30 and the lock member 40.

To detach the power supply unit 10 from the frame 30, the protrusions 316 are pressed inwards, to deform the resilient tabs 315. The protrusions 316 are disengaged from the openings 412, and the stop plates 47 are pulled upwards to detach the lock member 40 from the frame 30. Thereby, the power supply unit 10 can be taken out of the frame 30.

In other embodiments, the sizes of the openings 412 are designed to equal to the sizes of the protrusions 316, to allow the protrusions 316 to engage in the respective openings 412.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A mounting apparatus for a power supply unit, comprising:
a bottom plate;
a frame mounted on the bottom plate for receiving the power supply unit, the frame comprising two opposite side plates and an end plate connected between front ends of the side plates, wherein a resilient tab is formed on each side plate, and a protrusion is formed on an outer surface of each resilient tab; and
a lock member detachably mounted on the frame, the lock member comprising two opposite sidewalls, a top wall connected between tops of the sidewalls, and a stop plate extending down from a rear end of the top wall, wherein the sidewalls respectively contact outer surfaces of the side plates, and each of the sidewalls defines an opening to allow a corresponding one of the protrusions to engage in.

2. The mounting apparatus of claim 1, wherein each resilient tab is bound by a top open and substantially U-shaped slot.

3. The mounting apparatus of claim 2, wherein a slanted surface is formed on a top of each protrusion.

4. The mounting apparatus of claim 3, wherein two poles protrude upwards from the bottom plate, respectively adjacent to the outer surfaces of the side plates of the frame, two flanges respectively extend outwards from bottoms of the sidewalls of the lock member in a substantially perpendicular manner, a through hole is defined in each flange, the poles are respectively extended through the through holes.

5. The mounting apparatus of claim 4, wherein a positioning tab extends upward from a top of each side plate, a through slot is defined in a joint of the top wall and each sidewall, to engage with a corresponding one of the positioning tab.

6. The mounting apparatus of claim 1, wherein the lock member is mounted on a rear portion of the frame, the frame further comprises a top plate connected between front portions of tops of the side plates.

7. The mounting apparatus of claim 1, wherein two fixing plates respectively extend from bottoms of the side plates in a substantially perpendicular manner, a plurality of screws is extended through the fixing plates and engages in the bottom plate, to fix the frame to the bottom plate.
